(19) United States
(12) Patent Application Publication
(10) Pub. No.: US 2023/0357930 A1
(43) Pub. Date: Nov. 9, 2023

(54) SUPPORT FOR SEMICONDUCTOR SUBSTRATES FOR PECVD TREATMENT WITH HIGH SUBSTRATE LOADING CAPACITY

(71) Applicant: SEMCO SMARTECH FRANCE, CASTRIES (FR)

(72) Inventors: Bachir SEMMACHE, CASTRIES (FR); Guy LAZZARELLI, CASTRIES (FR); Tich Duy NGUYEN, CASTRIES (FR)

(21) Appl. No.: 18/044,264

(22) PCT Filed: Sep. 17, 2021
(86) PCT No.: PCT/EP2021/075571

§ 371 Date: Mar. 7, 2023

(30) Foreign Application Priority Data
Sep. 25, 2020 (FR) 20/09792

(51) Int. Cl. C23C 16/458; H01J 37/32

(52) U.S. Cl. CPC C23C 16/4587; C23C 16/4581; H01J 37/32715; H01L 31/182

(57) ABSTRACT

The present description concerns a support (54) for semiconductor substrates (26) comprising an assembly of trays (58A, 58B, 58C, 58D) having the semiconductor substrates resting thereon. Each tray is made of an electrically-conductive material and has at least one substantially vertical surface having locations arranged in at least two horizontally-oriented rows and two vertically-oriented columns. Each location receives a semiconductor substrate oriented with an inclination relative to a vertical direction varying from 1° to 10°. Each tray comprises, at each location, a recess or a cavity covered with the substrate (56). The trays of each pair of trays facing each other are separated by electrically-insulating spacers (60).

The present application claims the priority benefit of French patent application number 2009792, filed on Sep. 25, 2020 and entitled “Support pour substrats semiconducteurs pour traitement PECVD avec forte capacité de chargement de substrats”, the content of which is incorporated herein by reference as authorized by law.

### TECHNICAL BACKGROUND

The present application concerns a support for semiconductor substrates, particularly semiconductor substrates intended for the manufacturing of photovoltaic cells.

### PRIOR ART

A photovoltaic cell manufacturing method may comprise a step of depositing an electrically-insulating layer on a surface of a semiconductor substrate, particularly a silicon substrate, for example, according to a plasma-enhanced chemical vapor deposition or PECVD method.

FIG. 1 partially and schematically shows a side view with a partial cross-section of an example of a semiconductor substrate treatment device 10 capable of implementing a PECVD method.

Device 10 comprises an enclosure 12 having a substantially horizontal axis and where a reduced pressure is maintained. Device 10 further comprises a support 13 having trays 14 oriented substantially vertically and arranged next to one another arranged thereon, a single tray 14 being shown in FIG. 1. Trays 14 may be introduced into enclosure 12 or removed from enclosure 12 through a door 15, for example provided at one end of enclosure 12. Each tray 14, for example, made of graphite, may receive at least one semiconductor substrate 16. Semiconductor substrates 16 are arranged substantially vertically in enclosure 12.

FIG. 2 is a side view of a tray 14 comprising a row of semiconductor substrates 16.

Device 10 comprises tanks 18 containing precursor gases and optionally a neutral gas. Tanks 18 are connected to a control panel 20 adapted to forming a mixture of the precursor gases and optionally of the neutral gas. Control panel 20 is connected to enclosure 12 by a valve 22 which, when open, enables to introduce the gaseous mixture into enclosure 12 through a feed nozzle 23. Device 10 comprises a vacuum pump 24 connected to enclosure 12 by a valve 26 which, when open, enables to place enclosure 12 under vacuum and to suck in the gas mixture present in enclosure 12 through a suction port 25.

Device 10 further comprises heating elements 28 surrounding enclosure 12 and enabling to control the temperature of trays 14 and of the gaseous mixture in enclosure 12. Device 10 further comprises a generator 30 of an AC voltage which is electrically connected to trays 14 in enclosure 12.

The PECVD method is a technique of dry deposition, that is, from a gaseous phase. It uses the precursor gases which are injected into enclosure 12 and the deposition results from the decomposition of these gases by a chemical reaction at the surface of substrates 16. In the PECVD method, the chemical reaction is enhanced by an electric radio frequency discharge (RF) which ionizes the gases and forms a plasma. Each tray 14 acts as a heat conductor also providing a radio frequency contact with the associated semiconductor substrate 16. Trays 14 are connected to generator 30 to form an alternation of cathodes and of anodes and a plasma is generated between each pair of adjacent trays 14. The precursor gases will decompose to form a thin film deposit on the surface of each substrate 16 opposite to the surface in contact with tray 14.

It would be desirable to increase the treatment capacity of device 10, that is, the number of semiconductor substrates 16 capable of being simultaneously treated. With device 10, this may be done by increasing the number of trays 14 and/or by increasing the number of semiconductor substrates 16 per row and/or by increasing the number of rows per trays 14.

However, it may be difficult to increase the number of substrates per row, given that the handling of semiconductor substrates 16 to arrange them on tray 14 and to remove them from trays 14 may become complex or even impossible in the horizontal configuration of device 10. Indeed, the loading of substrates 26 is only possible from top to bottom and perpendicularly to the horizontally-arranged tray 14. Further, the increase in the number of trays 14, and the increase in the number of rows per tray 14 cause a significant increase in the length of enclosure 12 and of the footprint of device 10, which is not desirable for a use at an industrial scale.

### SUMMARY

An object of an embodiment aims at overcoming all or part of the disadvantages of the previously-described treatment devices.

An object of an embodiment is for the footprint of the treatment device to be decreased.

An object of an embodiment is for the capacity of the treatment device to be able to be increased.

An embodiment provides a support for semiconductor substrates comprising an assembly of trays having the semiconductor substrates resting thereon, each tray being made of an electrically-conductive material and having at least one substantially vertical surface having locations arranged in at least two horizontally-oriented rows and two vertically-oriented columns, each location receiving a semiconductor substrate oriented with an inclination relative to a vertical direction varying from 1° to 10°, each tray comprising, at each location, a recess or a cavity covered with the substrate, the trays of each pair of trays facing each other being separated by electrically-insulating spacers.

According to an embodiment, said surface of each tray has locations arranged in at least three horizontally-oriented rows and two vertically-oriented columns, each location receiving a semiconductor substrate oriented with an inclination relative to a vertical direction varying from 1° to 10°.

According to an embodiment, said surface of each tray has locations arranged in at least five horizontally-oriented rows and two vertically-oriented columns, each location receiving a semiconductor substrate oriented with an inclination relative to a vertical direction varying from 1° to 10°.

According to an embodiment, said surface of each tray has locations arranged in from five to ten horizontally-oriented rows and two vertically-oriented columns, each location receiving a semiconductor substrate oriented with an inclination relative to a vertical direction varying from 1° to 10°.

According to an embodiment, the support comprises from 10 to 40 trays.

According to an embodiment, the assembly of trays comprises inner trays sandwiched between two outer trays, each inner tray having two parallel substantially vertical surfaces, each having locations arranged in at least two horizontally-oriented rows and two vertically-oriented columns, each location of each surface receiving a semiconductor substrate oriented with an inclination relative to a vertical direction varying from 1° to 10°.

According to an embodiment, the two outer trays each comprise a single substantially vertical surface having locations arranged in at least two horizontally-oriented rows and two vertically-oriented columns, each location receiving a semiconductor substrate oriented with an inclination relative to a vertical direction varying from 1° to 10°.

According to an embodiment, each inner tray comprises, at each location, a through recess covered on each of the two surfaces of the inner tray by one of the substrates.

According to an embodiment, each outer tray comprises, at each location, a non-through cavity in said surface of the outer tray, covered with the substrate.

According to an embodiment, each tray comprises at least one tab, the support comprising at least a first electrically-conductive rod connected to the tabs of first trays of said assembly of trays and a second electrically-conductive rod connected to the tabs of second trays of said assembly of trays, said assembly comprising an alternation of the first and second trays.

According to an embodiment, each tray comprises, for each location, pads protruding from said surface and which are in contact with the semiconductor substrate present at said location.

An embodiment also provides a device for treating semiconductor substrates, the device comprising an enclosure having a substantially vertical axis and at least one circuit for feeding a gaseous mixture into the enclosure, the device further comprising, in the enclosure, at least one support of the semiconductor substrates such as previously defined, the treatment device further comprising at least one radio frequency generator of an AC voltage electrically coupled to a plurality of said trays.

According to an embodiment, the device comprises a vacuum pump connected to the enclosure.

According to an embodiment, the enclosure is made of stainless steel.

According to an embodiment, the device is used for the treatment of semiconductor substrates intended for the manufacturing of photovoltaic cells.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1, previously described, partially and schematically shows an example of a device for treating semiconductor substrates by PECVD;

FIG. 2, previously described, partially and schematically shows an example of a tray provided with semiconductor substrates of the treatment device of FIG. 1;

FIG. 3 is a partial simplified cross-section view of an embodiment of a device of PECVD treatment of semiconductor substrates;

FIG. 4 partially and schematically shows an embodiment of a semiconductor substrate support of the treatment device of FIG. 3;

FIG. 5 partially and schematically shows an embodiment of a first tray provided with semiconductor substrates of the support of FIG. 4, the tray comprising two columns and six rows;

FIG. 6 partially and schematically shows an embodiment of a second tray provided with semiconductor substrates of the support of FIG. 4;

FIG. 7 is a partial simplified top cross-section view of the PECVD treatment device of semiconductor substrates of FIG. 3 with an embodiment of the semiconductor substrate support; and

FIG. 8 is a drawing similar to FIG. 7 with a variant of the semiconductor substrate support.

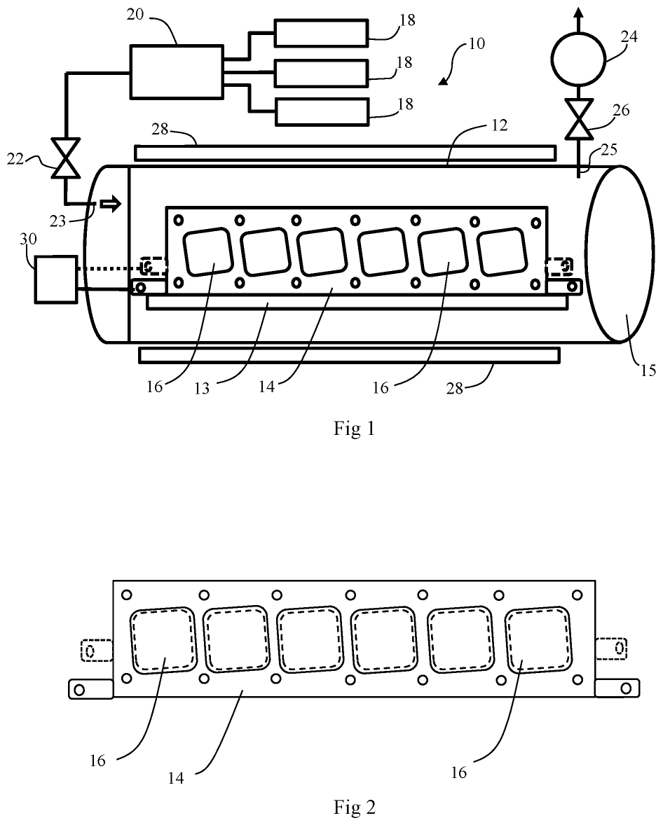

### DESCRIPTION OF THE EMBODIMENTS

Like features have been designated by like references in the various figures. In particular, the structural and/or functional features that are common among the various embodiments may have the same references and may dispose identical structural, dimensional and material properties. For the sake of clarity, only the steps and elements that are useful for an understanding of the embodiments described herein have been illustrated and described in detail. In the following description, when reference is made to terms qualifying a relative position, such as terms “top”, “bottom”, “upper”, “lower”, etc., reference is made to the vertical direction. Unless specified otherwise, the expressions “around”, “approximately”, “substantially” and “in the order of” signify within 10%, and preferably within 5%. The terms “about”, “approximately”, “substantially”, and “in the order of”, when they are associated with a direction, signify plus or minus 10°. Unless specified otherwise, the expressions “around”, “approximately”, “substantially” and “in the order of” signify within 10%, and preferably within 5%.

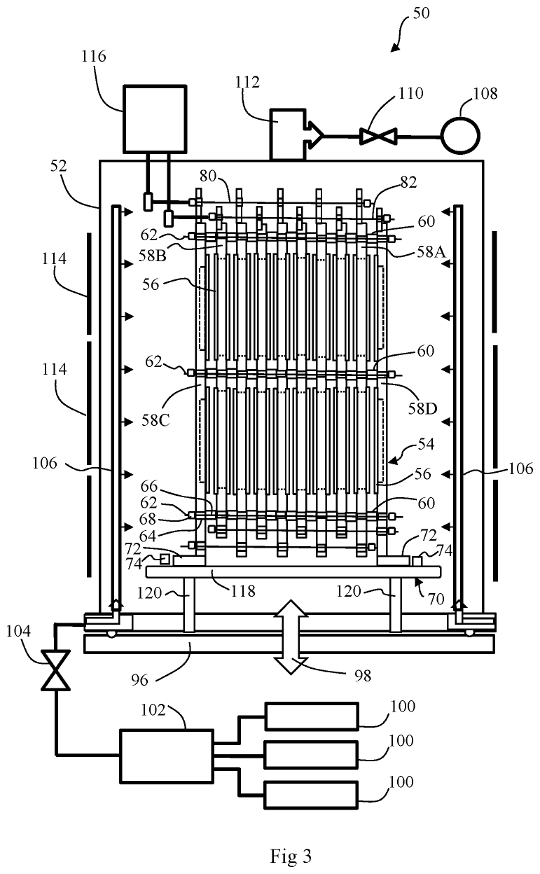

FIG. 3 shows a partial simplified side view with a cross-section of an embodiment of a device 50 for treating parts adapted to the implementation of a PECVD method.

Device 50 comprises a vertically-oriented tight enclosure 52, for example, made of stainless steel or of quartz, where a low pressure can be maintained. In the case where enclosure 52 is made of stainless steel, a treatment of the inner wall of enclosure 52 may be carried out. The specifications to be respected in terms of mechanical and thermal resistance may, advantageously, be less constraining when enclosure 52 is made of stainless steel than in the case where enclosure 52 is made of quartz. Enclosure 52 may have a substantially cylindrical shape with a vertical axis. Device 50 further comprises a support 54, also called boat, for semiconductor substrates 56. Boat 54 comprises an alternation of inner trays 58A and 58B made of an electrically-conductive material. The alternation of inner trays 58A and 58B is sandwiched between two outer trays 58C and 58D. Each tray 58A, 58B, 58C, 58D is made of a conductive material, for example, of graphite. The trays of each pair of adjacent trays 58A, 58B, 58C, and 58D are separated by spacers 60 made of an electrically-insulating material. Spacers 60 are for example made of ceramic.

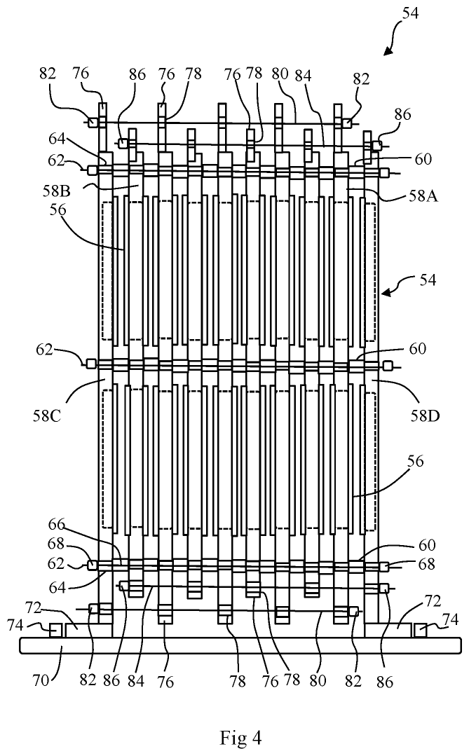

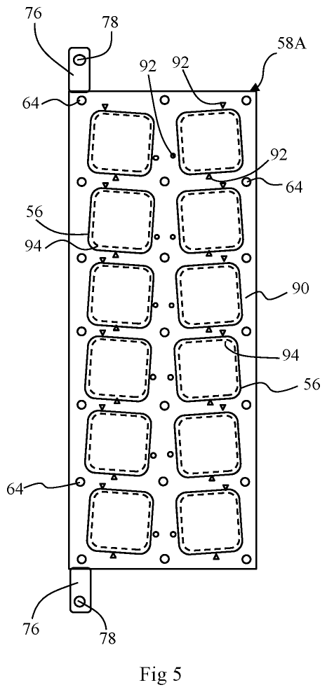

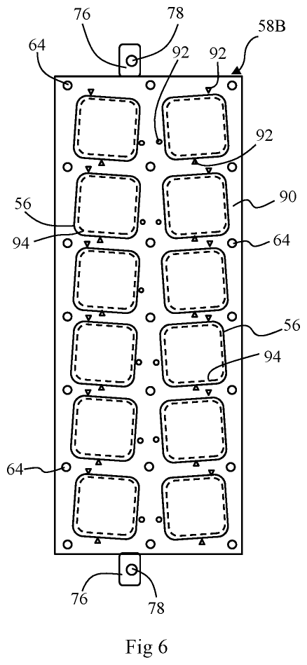

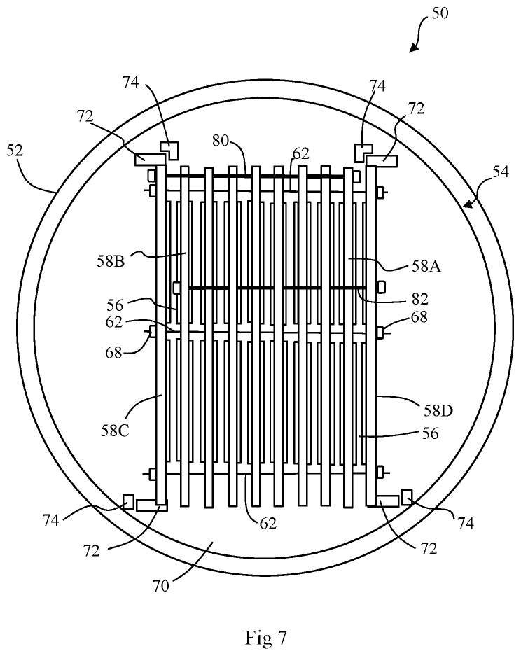

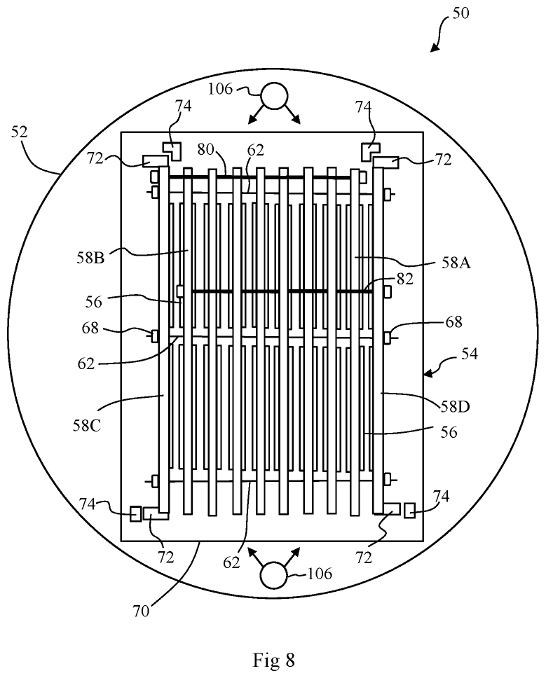

FIG. 4 is a partial simplified side view with a cross-section of an embodiment of boat 54. FIGS. 5 and 6 are partial simplified side views, respectively of inner trays 58A and 58B loaded with semiconductor substrates 56, the views of FIGS. 5 and 6 being along a horizontal direction orthogonal to the direction of the view of FIG. 4. FIG. 7 is a partial simplified top view with a cross-section of device 50, and FIG. 8 is a view similar to FIG. 7 of a variant of device 50. Spacers 60 are not shown in FIGS. 7 and 8.

Trays 58A, 58B, 58C, 58D are rigidly coupled to one another. According to an embodiment, boat 54 comprises rods 62 made of an electrically-insulating material, for example, of ceramic. Each tray 58A, 58B, 58C, 58D comprises through holes 64 for the passage of rods 62. Similarly, each spacer 60 comprises a through hole 66 for the passage of a rod 62. Each rod 62 thus extends through holes 64 and 66, by alternately running through one of trays 58A, 58B, 58C, 58D and one of spacers 60. For each rod 62, nuts 68, made of an electrically-insulating material, for example, of ceramic, screwed to the ends of rod 62 hold in compression the assembly of trays 58A, 58B, 58C, 58D and of spacers 62. According to an embodiment, rods 62 are substantially parallel.

Boat 54 comprises a pedestal 70, made of an electrically-insulating material, having trays 58A, 58B, 58C, 58D resting thereon. According to an embodiment, the output trays 58C and 58D comprise feet 72 coming into contact with pedestal 70, while inner trays 58A and 58B do not come into contact with pedestal 70. Pedestal 70 may comprise guides 74 adapted to cooperating with feet 72 during the placing of trays 58A, 58B, 58C, 58D on pedestal 70.

Inner trays 58A are electrically coupled together and to outer tray 58C. Inner trays 58B are electrically coupled together and to outer tray 58D. For this purpose, each tray 58A, 58B, 58C, 58D comprises at least one tab 76 crossed by a hole 78. In FIGS. 3 to 8, trays 58A, 58B, 58C, 58D are shown with two tabs 76, one in the upper portion of the tray and the other one in the lower portion of the tray. As appears in FIGS. 5 and 6, trays 58A and 58B have substantially the same structure and differ by the position of tabs 76.

According to an embodiment, boat 54 comprises first rods 80 made of an electrically-conductive material, for example, of graphite, running through the holes 78 of inner trays 58A and of outer tray 58C while being in contact with inner trays 58A and outer tray 58C. For each first conductive rod 80, nuts 82, made of an electrically-conductive material, for example, of graphite, attached to the ends of rod ensure the holding of rod 80. According to an embodiment, boat 54 comprises second rods 84 made of an electrically-conductive material, for example, of graphite, running through the holes 78 of inner trays 58B and of outer tray 58D while being in contact with inner trays 58B and outer tray 58D. For each second conductive rod 84, nuts 86, made of an electrically-conductive material, for example, of graphite, attached to the ends of rod 84 ensure the holding of rod 84. According to an embodiment, firsts and second rods 80, 84 are substantially parallel.

Each tray 58A, 58B, 58C, 58D comprises a substantially planar tray 90, oriented substantially vertically, having tabs 76 projecting therefrom, and having locations, each intended to receive a semiconductor substrate 56, provided thereon. Each inner tray 58A, 58B comprises two opposite surfaces, substantially vertical, each surface of inner tray 58A, 58B comprising locations, each intended to receive a semiconductor substrate 56. The surface of semiconductor substrate 56 intended to be treated is that oriented towards the space between two adjacent trays. Each outer tray 58C, 58D comprises locations, each intended to receive a semiconductor substrate 56 on a single surface, substantially vertical, of tray 58C, 58D located opposite one of inner trays 58A, 58B.

Semiconductor substrates 56 are arranged substantially vertically on trays 58A, 58B, 58C, 58D. According to an embodiment, substrates 56 are vertically installed on trays 58A, 58B, 58C, 58D with a slight inclination relative to the vertical direction ensuring their stability with respect to their center of gravity. The angle of inclination relative to the vertical direction varies from 1° to 10°, preferably from 2° to 6° according to the size of substrates 56. On each tray 58A, 58B, 58C, 58D, semiconductor substrates 56 are arranged in rows and in columns. According to an embodiment, each tray 58A, 58B, 58C, 58D comprises locations for at least one column of semiconductor substrates 56, preferably for two columns of semiconductor substrates 56. According to an embodiment, each tray 58A, 58B, 58C, 58D comprises locations for at least two rows of semiconductor substrates 56, preferably for at least four rows of semiconductor substrates 56, more preferably at least eight rows of semiconductor substrates 56. The number of trays 58A, 58B, 58C, 58D may be in the range from 5 to 100, preferably from 10 to 40. In particular, the number of trays 58A, 58B, 58C, 58D depends on the diameter of the enclosure 52 receiving boat 54. In FIGS. 3, 4, 7, and 8, the shown boat 54 comprises ten trays 58A, 58B, 58C, 58D, and each inner tray 58A, 58B comprises locations for two rows and two columns of semiconductor substrates 56 on each surface and each outer tray 58C, 58D comprises locations for two rows and two columns of semiconductor substrates 56. In FIGS. 5 and 6, each shown inner tray 58A and 58B comprises locations for two columns and six rows of semiconductor substrates 56 on each surface. As an example, a boat of thirty trays with two columns and seven rows each may contain 812 semiconductor substrates. Generally, an increase in the diameter of enclosure 52 may enable to increase the number of trays 58A, 58B of boat 54 and an increase in the height of enclosure 52 may enable to increase the number of rows of boat 54.

According to an embodiment, each tray 58A, 58B, 58C, 58D comprises, for each location, pads or pins 92 intended to abut against semiconductor substrate 56. At least some of pads 92 are adapted to maintaining substrate 56 pressed against tray 58A, 58B, 58C, 58D. In FIGS. 5 and 6, each tray 58A, 58B, 58C, 58D comprises three pads 92 for each location. Each pad 92 may have a conical or frustoconical shape projecting from the surface of tray 90. Each pad 92 may project in relief from the surface of tray 90 along a height for example in the range from 0.5 mm to 2 mm, for example, in the order of 1 mm.

According to an embodiment, each inner tray 58A, 58B comprises, for each location, a recess or a cavity 94 intended to be covered with semiconductor substrate 56. The contour of recesses 94 is indicated in dashed lines in FIGS. 3, 4, 5, and 6. Recesses 94 may preferably be through. Advantageously, this particularly enables to decrease the weight of the tray, to decrease the thermal inertia of boat 54 as well as its electric resistance. According to an embodiment, outer trays 58C, 58D do not comprise a through recess for each location, but may comprise, for each location, a non-through recess, also called cavity, intended to be covered with semiconductor substrate 56. The dimensions of each recess 94 are selected so that, when semiconductor substrate 56 is in position on inner tray 58A, 58B, it substantially entirely covers the underlying recess and is in contact with tray 90 on its circumference only.

According to an embodiment, the spacing between two adjacent trays 58A, 58B, 58C, 58D is substantially constant, for example, in the range from 10 mm to 20 mm, preferably from 10 mm to 12 mm. The maximum thickness of each tray 58A, 58B, 58C, 58D is in the range from 1 mm to 10 mm, preferably from 2 mm to 5 mm, for example, in the order of 5 mm. Each semiconductor substrate 56 may have a thickness in the range from 100 μm to 200 μm. Each substrate 56 may, in the side view of FIGS. 5 and 6, have a substantially square shape, possible with rounded corners, having a side length in the range from 100 mm to 220 mm. Generally, each substrate 56 may, in the side view of FIGS. 5 and 6, have a square or substantially square (generally known as full square or pseudo-square), rectangular, or circular shape.

Device 50 comprises means, not shown, for displacing boat 54, particularly to introduce it into enclosure 52 or to take it out of enclosure 52. The displacement means may comprise an articulated arm. Enclosure 52 comprises a gate 96, for example, located at the base of enclosure 52, which, when it is open, enables to introduce or to take out boat 54 into and from enclosure 52 (arrow 98 in FIG. 3). As a variant, gate 96 may be coupled to boat 54 and may tightly close enclosure 52 when boat 54 is introduced into enclosure 52.

Device 50 comprises tanks 100 containing precursor gases and optionally at least one neutral gas and optionally a vaporization and vapor regulation system to supply a precursor gas from a liquid precursor container. Containers 100 are connected, particularly via mass flow regulators, to a control panel 102 capable of forming a gaseous mixture, containing precursor gases and optionally at least one neutral gas, which depends on the treatment to be performed. Control panel 102 is coupled to enclosure 52 by a valve 104 which, when it is open, enables to introduce the gaseous mixture into enclosure 52 through an inlet duct 106. As a variant, certain gases or vapor-phase liquids may be possibly regulated and introduced into the enclosure independently from a mixer.

Device 50 comprises a vacuum pump 108 connected to enclosure 52 by one or a plurality of valves 110. As an example, a single valve 110 is shown in FIG. 3 which, when open, allows the pumping of the gaseous mixture present in enclosure 52 by a pumping channel 112. According to an embodiment, pumping channel 112 is located at the top of enclosure 52 and the connections between feeder circuits 100 and 102 and enclosure 52 are located at the base of enclosure 52. As a variant, pumping channel 112 may be located at the base of enclosure 52 and the connections between feeder circuits 100 and 102 and enclosure 52 may be located at the top of enclosure 52.

Device 50 further comprises at least one heating element 114 surrounding enclosure 52, for example, electric resistors, enabling to control the temperature of trays 58A, 58B, 58C, 58D and of the gaseous mixture in enclosure 52. According to an embodiment, heating elements 114 may be controlled independently from one another.

Device 50 further comprises at least one generator 116 of an AC voltage coupled to trays 58A, 58B, 58C, 58D. Inner trays 58A and outer tray 58C are connected to a first terminal of generator 116 of the AC voltage and inner trays 58B and outer tray 58D are connected to a second terminal of generator 116. Two adjacent trays 58A, 58B, 58C, 58D are electrically insulated from one another by spacers 60.

Pedestal 70 may comprise a base 118 having a planar surface having boat 54 resting thereon and feet 120, corresponding, for example, to ceramic rods, extending from base 118 and allowing the manipulation of pedestal 70. As an example, boat 54 may be installed on pedestal 70, which is attached to gate 96 via feet 120. FIG. 7 shows a pedestal 70 having its base 188 having, in top view, a shape complementary to the inner shape of enclosure 52, for example, a disk shape. FIG. 8 shows a pedestal 70 having its base 118 having, in top view, a rectangle shape. This version eases the installation of reactive gas injection systems according to the height of the deposition enclosure.

The operation of device 50 will now be described in the case of a PECVD method.

According to an embodiment, boat 54 is mounted by assembly of trays 58A, 58B, 58C, 58D and spacers 60. Boat 54 may be used for a plurality of successive deposition operations. A maintenance operation on support 54 may be provided after a plurality of deposition operations and may comprise disassembling support 54 and cleaning trays 58A, 58B, 58C, 58D.

According to another embodiment, boat 54 may be handled by means of an articulated arm which ensures its displacement towards and out of the enclosure. In this configuration, the boat is used for a number of depositions before being replaced with a new clean boat. Accordingly, the used boat may be cleaned in masked time and be ready to be subsequently reused.

Semiconductor substrates 56 are arranged on trays 58A, 58B, 58C, 58D. According to an embodiment, the arranging of substrates 56 on trays 58A, 58B, 58C, 58D is carried out by using a robot provided with a gripper, for example, a Bernoulli chuck. The dimensions of the gripper are adapted to enable to insert the gripper provided with a substrate 56 or a plurality of substrates 56 into the space present between two adjacent trays 58A, 58B, 58C, 58D. A multiple gripper enables to load a tray surface on a row and a column and then to pass to the second surface of the tray of the same row and column. The same operation is performed on the other rows. The loading of the second column is performed either by turning by 180° the boat at the level of the station of the loading robot or via a second robot located on the opposite side. In this last case, the loading of the two columns may be performed simultaneously at the level of the substrate loading station.

Boat 54 loaded with semiconductor substrates 56 is then introduced into enclosure 52.

In operation, the gaseous mixture is introduced into enclosure 52 via feed ducts 106. Each tray 58A, 58B, 58C, 58D acts as a heat conductor and as an element of radio frequency contact with the semiconductor substrates 56 resting thereon. Trays 58A, 58B, 58C, 58D are coupled to generator 116 to form an alternation of cathodes and of anodes and a plasma is generated between each pair of adjacent trays 58A, 58B, 58C, 58D. As an example, the frequency of the plasma controlled by each generator 116, 88 is in the range from 40 kHz to 2.45 GHz, for example, in the order of 50 kHz. According to an embodiment, generator 116 applies the AC voltage to the associated trays 58A, 58B, 58C, 58D in pulsed fashion, that is, by periodically alternating a phase tₒₙ of application of the AC voltage and a phase t_{off} when the AC voltage is not applied. The period of the pulses may vary between 10 ms and 200 ms. The duty cycle of the pulses, that is, the ratio of the duration of phase tₒₙ to the period of the pulses may be approximately 10%.

Heating elements 114 may be controlled to obtain a uniform temperature in enclosure 52 or to obtain a temperature gradient in enclosure 52, for example, along the vertical direction. According to the treatment performed, the temperature in enclosure 52 may be regulated between 200° C. and 600° C.

According to an embodiment, each substrate 56 is a single-crystal silicon or polysilicon substrate and device 50 is used to deposit a thin layer, for example, an electrically-insulating layer, on the upper surface of each substrate 56. As a variation, the treatment device may be used to carry out semiconductor substrate etching operations, particularly plasma etching operations. The insulating layer may be a layer of silicon nitride (SiNₓ), of silicon oxide (SiOₓ), of silicon oxynitride (SiOₓN_{y}), of silicon carbide (SiC), of silicon carbonitride (SiCN), of aluminum oxide (AlOₓ), of borosilicate glass, of phosphosilicate glass, or of boron- or phosphorus-doped or intrinsic amorphous silicon. The gases introduced into enclosure 52 may be selected from the group comprising silane (SiH₄), ammonia (NH₃), trimethylaluminum (TMA), nitrogen protoxide (N₂O), nitrogen trifluoride (NF₃), methane (CH₄), boron trichloride (BCl₃), dioxygen (O₂), nitrogen (N₂), argon (Ar), diborane (B₂H₆), phosphine (PH₃), trimethylborate (TMB), trimethylphosphate (TMP), and triethylorthosilicate (TEOS). The thickness of the deposited layer may be in the range from 5 nm to 150 nm, preferably from 10 nm to 100 nm, for example, in the order of 40 nm.

Vacuum pump 108 is started to maintain a pressure in enclosure 52 in the range from 67 Pa (approximately 0.5 Torr) to 667 Pa (approximately 5 Torr). According to an embodiment, vacuum pump 108 may operate continuously. An isolation valve, provided between vacuum pump 108 and pumping channel 112, enables to interrupt the pumping performed by the vacuum pump and a regulation valve, provided between vacuum pump 108 and pumping channel 112, enables to control the pressure in enclosure 52 according to the pumping rate.

The precursor gases will decompose to form a deposit of a thin film on the exposed surface of substrates 56.

At the end of the treatment, boat 54 is removed from enclosure 52 and the treated substrates 56 are removed from each tray 58A, 58B, 58C, 58D.

Advantageously, the distance between two adjacent trays 58A, 58B, 58C, 58D of boat 54 is substantially constant. The design of boat 54 is then simplified and the installing of semiconductor substrates 56 on trays 58A, 58B, 58C, 58D, for example, in automated fashion, is also simplified.

Recesses 94 enable air to freely flow under substrate 56, which is favorable to the proper operation of a Bernoulli chuck, particularly when substrate 56 is removed from tray 58A, 58B, 58C, 58D and avoids the risk of adhesion of substrate 56 on tray 58A, 58B, 58C, 58D which might result from too significant a direct surface contact between substrate 56 and tray 58A, 58B, 58C, 58D.

Device 50 advantageously has a small footprint. Further, an increase in the treatment capacity of device 50 may be achieved by increasing the number of rows per tray 58A, 58B, 58C, 58D, and thus advantageously without causing a change in the footprint of device 50. The height of the boat is limited by the height to the ceiling after opening of device 50. The height to the ceiling of photovoltaic cell production lines is generally set to approximately 4 meters.

Various embodiments and variants have been described. Those skilled in the art will understand that certain features of these various embodiments and variants may be combined, and other variants will occur to those skilled in the art. In particular, although examples of thin film deposition treatment have been described, the treatment device may be used to perform operations of etching of semiconductor substrates or of silicon-based thin films, particularly plasma etching operations.

Finally, the practical implementation of the described embodiments and variations is within the abilities of those skilled in the art based on the functional indications given hereabove.

1. A support for semiconductor substrates comprising:
an assembly of trays having the semiconductor substrates resting thereon, each tray being made of an electrically-conductive material and having at least one substantially vertical surface having locations arranged in at least two horizontally-oriented rows and two vertically-oriented columns, each location being configured to receive a semiconductor substrate oriented with an inclination relative to a vertical direction varying from 1° to 10°, each tray comprising, at each location, a recess or a cavity covered with the substrate, the trays of each pair of trays facing each other being separated by electrically-insulating spacers.

2. The support according to claim 1, wherein said surface of each tray has locations arranged in at least three horizontally-oriented rows and two vertically-oriented columns.

3. The support according to claim 2, wherein said surface of each tray has locations arranged in at least five horizontally-oriented rows and two vertically-oriented columns.

4. The support according to claim 3, wherein said surface of each tray has locations arranged in from five to ten horizontally-oriented rows and two vertically-oriented columns.

5. The support according to claim 1, comprising from 10 to 40 trays.

6. The support according to claim 1, wherein the assembly of trays comprises inner trays sandwiched between two outer trays, each inner tray having two parallel substantially vertical surfaces, each having locations arranged in at least two horizontally-oriented rows and two vertically-oriented columns, each location of each surface receiving a semiconductor substrate oriented with an inclination relative to a vertical direction varying from 1° to 10°.

7. The support according to claim 6, wherein the two outer trays each comprise a single substantially vertical surface having locations arranged in at least two horizontally-oriented rows and two vertically-oriented columns, each location receiving a semiconductor substrate oriented with an inclination relative to a vertical direction varying from 1° to 10°.

8. The support according to claim 5, wherein each inner tray comprises, at each location, a through recess intended to be covered on each of the two surfaces of the inner tray by one of the substrates.

9. The support according to claim 6, wherein each outer tray comprises, at each location, a non-through cavity in said surface of the outer tray, intended to be covered with the substrate.

10. The support according to claim 1, wherein each tray comprises at least one tab, the support comprising at least one first electrically-conductive rod connected to the tabs of first trays of said assembly of trays and a second electrically-conductive rod connected to the tabs of second trays of said assembly of trays, said assembly comprising an alternation of the first and second trays.

11. The support according to claim 1, wherein each tray comprises, for each location, pads protruding from said surface and which are configured to be in contact with the semiconductor substrate present at said location.

12. A device for treating semiconductor substrates, the device comprising:
an enclosure having a substantially vertical axis and at least one circuit for feeding a gaseous mixture into the enclosure, the device further comprising, in the enclosure, at least one support of the semiconductor substrates according to claim 1, the treatment device further comprising at least one radio frequency generator of an AC voltage electrically coupled to a plurality of said trays.

13. The device according to claim 12, comprising a vacuum pump coupled to the enclosure.

14. The device according to claim 12, wherein the enclosure is made of stainless steel.

15. The device according to claim 12, for the treatment of semiconductor substrates intended for photovoltaic cell manufacturing.
